(19) United States
(12) Patent Application Publication
(10) Pub. No.: US 2022/0223641 A1
(43) Pub. Date: Jul. 14, 2022

(54) IMAGE SENSOR PACKAGE HAVING A CAVITY STRUCTURE FOR A LIGHT-TRANSMITTING MEMBER

(71) Applicant: SEMICONDUCTOR COMPONENTS INDUSTRIES, LLC, Phoenix, AZ (US)

(72) Inventors: Larry Duane KINSMAN, Redding, CA (US); Yu-Te HSIEH, Taoyuan City (TW)

(73) Assignee: SEMICONDUCTOR COMPONENTS INDUSTRIES, LLC, Phoenix, AZ (US)

(21) Appl. No.: 17/248,209

(22) Filed: Jan. 14, 2021

(51) Int. Cl. H01L 27/146; H01L 31/18

(52) U.S. Cl. CPC H01L 27/14618; H01L 27/14698; H01L 31/1876; H01L 27/14636

(57) ABSTRACT

According to an aspect, an image sensor package includes a substrate, an image sensor die coupled to the substrate, at least one conductor connected to the image sensor die and the substrate, and a light-transmitting member including a substrate member, a first leg member extending from a first edge portion of the substrate member, and a second leg member extending from a second edge portion of the substrate member, the first leg member being coupled to the substrate, the second leg member being coupled to the substrate.

### TECHNICAL FIELD

This description relates to an image sensor package having a cavity structure for a light-transmitting member.

### BACKGROUND

An image sensor package may use a bonding material to couple a glass substrate to an image sensor die. Also, the bonding material may operate as a dam member in which the bonding material positions the glass substrate at a location away from an active area of the image sensor die, where the bonding material is disposed on a non-active area of the image sensor die. However, for some conventional image sensor packages, thermal and/or moisture stress may lead to the delamination of the glass bonding interface and potentially moisture intrusion into the active region of the image sensor die.

### SUMMARY

According to an aspect, an image sensor package includes a substrate, an image sensor die coupled to the substrate, at least one conductor connected to the image sensor die and the substrate, and a light-transmitting member including a substrate member, a first leg member extending from a first edge portion of the substrate member, and a second leg member extending from a second edge portion of the substrate member, the first leg member being coupled to the substrate, the second leg member being coupled to the substrate.

According to some aspects, the image sensor package may include one or more of the following features. The light-transmitting member includes a cavity that extends between the first leg member and the second leg member. The image sensor die is disposed within the cavity. At least a portion of the at least one conductor is disposed within the cavity. The first leg member is coupled to the substrate with a bonding material, and the second leg member is coupled to the substrate with a bonding material. The substrate member is a linear body having a length greater than a length of the image sensor die, where the substrate member includes a first surface and a second surface. The first leg member extends from the second surface at a first non-zero angle with respect to the second surface. The second leg member extends from the second surface at a second non-zero angle with respect to the second surface. The first non-zero angle is a perpendicular angle, and the second non-zero angle is a perpendicular angle. The image sensor package may include an encapsulation material including a first portion that contacts at least a portion of the first leg member and a second portion that contacts at least a portion of the second leg member. The substrate includes a first surface and a second surface. The image sensor die is coupled to the first surface. The image sensor package includes a plurality of conductive components coupled to the second surface of the substrate, where the plurality of conductive components are configured to be connected to an external device. The image sensor package is an interstitial ball grid array (iBGA) package.

According to an aspect, an image sensor strip assembly having multiple image sensor packages, where the image sensor strip assembly includes a substrate, a first image sensor die coupled to a first portion of the substrate, and a first light-transmitting member coupled to the first portion of the substrate. The first light-transmitting member includes a substrate member, a first leg member extending from the substrate member, and a second leg member extending from the substrate member. The image sensor strip assembly includes a second image sensor die coupled to a second portion of the substrate, and a second light-transmitting member coupled to the second portion of the substrate. The second light-transmitting member includes a substrate member, a first leg member extending from the substrate member, and a second leg member extending from the substrate member.

According to some aspects, the image sensor strip assembly includes an encapsulation material including a portion disposed between the second leg member of the first light-transmitting member and the first leg member of the second light-transmitting member. The image sensor strip assembly includes a third image sensor die coupled to a third portion of the substrate, and a third light-transmitting member coupled to the third portion of the substrate. The third light-transmitting member includes a substrate member, a first leg member extending from the substrate member, and a second leg member extending from the substrate member. The encapsulation material includes a portion disposed between the second leg member of the second light-transmitting member and the first leg member of the third light-transmitting member. The first leg member of the first light-transmitting member is coupled to the first portion of the substrate, and the second leg member of the first light-transmitting member is coupled to the first portion of the substrate. The image sensor strip assembly includes at least one first conductor connected to the first image sensor die and the first portion of the substrate, and at least one second conductor connected to the second image sensor die and the second portion of the substrate. The first leg member of the first light-transmitting member is coupled to the first portion of the substrate with a bonding material, and the second leg member of the first light-transmitting member is coupled to the first portion of the substrate with a bonding material. The substrate member of the first light-transmitting member is a linear body having a length greater than a length of the first image sensor die, where the substrate member of the first light-transmitting member includes a first surface and a second surface, and the first leg member of the first light-transmitting member extends from the second surface at a perpendicular angle with respect to the second surface, and the second leg member of the first light-transmitting member extends from the second surface at a perpendicular angle with respect to the second surface. The substrate includes a first surface and a second surface, where the first image sensor die is coupled to the first surface, and the second image sensor die is coupled to the first surface. The image sensor strip assembly includes a plurality of solder balls coupled to the second surface of the substrate, where the plurality of solder balls is configured to be connected to an external device.

According to an aspect, a method of creating individual image sensor packages includes receiving an image sensor strip assembly, where the image sensor strip assembly includes a substrate, a first image sensor die coupled to a first portion of the substrate, and a first light-transmitting member coupled to the first portion of the substrate. The first light-transmitting member includes a substrate member, a first leg member extending from the substrate member, and a second leg member extending from the substrate member. The image sensor strip assembly includes a second image sensor die coupled to a second portion of the substrate, and a second light-transmitting member coupled to the second portion of the substrate, where the second light-transmitting member includes a substrate member, a first leg member extending from the substrate member, and a second leg member extending from the substrate member. The image sensor strip assembly includes an encapsulation material including a portion disposed between the second leg member of the first light-transmitting member and the first leg member of the second light-transmitting member. The method includes cutting the portion of the encapsulation material that is disposed between the second leg member of the first light-transmitting member and the first leg member of the second light-transmitting member, and cutting the substrate at a location between the first portion of the substrate and the second portion of the substrate.

According to an aspect, a method of forming an image sensor package includes etching a light-transmitting member to create a cavity structure, where the cavity structure is defined by a substrate member, a first leg member extending from a first edge portion of the substrate member, and a second leg member extending from a second edge portion of the substrate member. The method includes coupling an image sensor die to a substrate, connecting at least one conductor to the image sensor die and the substrate, and coupling the cavity structure to the substrate using a bonding material such that the first and second leg members are coupled to the substrate and the image sensor die is enclosed in the cavity structure.

The details of one or more implementations are set forth in the accompanying drawings and the description below. Other features will be apparent from the description and drawings, and from the claims.

### BRIEF DESCRIPTION OF THE DRAWINGS

FIG. 1A illustrates an image sensor package according to an aspect.

FIG. 1B illustrates a light-transmitting member of the image sensor package according to an aspect.

FIG. 2 illustrates an image sensor package according to another aspect.

FIG. 3 illustrates an image sensor package according to another aspect.

FIG. 4 illustrates an image sensor strip assembly having multiple image sensor packages according to an aspect.

FIG. 5 illustrates a flowchart depicting example operations of creating multiple image sensor packages from an image sensor strip assembly according to an aspect.

FIG. 6 illustrates a flowchart depicting example operations of assembling an image sensor package according to an aspect.

### DETAILED DESCRIPTION

The present disclosure relates to an image sensor package that includes a light-transmitting member that defines a cavity. The light-transmitting member includes a substrate member, a first leg member that extends from the substrate member (e.g., at a non-zero angle), and a second leg member that extends from the substrate member (e.g., at a non-zero angle). In some examples, the cavity of the light-transmitting member is formed by removing a portion of the light-transmitting member, thereby creating the first and second leg members in which the space between the first leg member and the second leg member defines the cavity. The first and second leg members are coupled to a substrate such that an image sensor die is positioned within the cavity of the light-transmitting member. The image sensor packages (and methods) discussed herein may reduce the development time to produce such packages and decrease production costs, as well as increase the durability of an image sensor package. Also, the image sensor package includes an encapsulation material that contracts the interface of the light-transmitting member and the substrate to protect the peripheral of the package side wall and assist with preventing delamination by thermal and/or moisture stress.

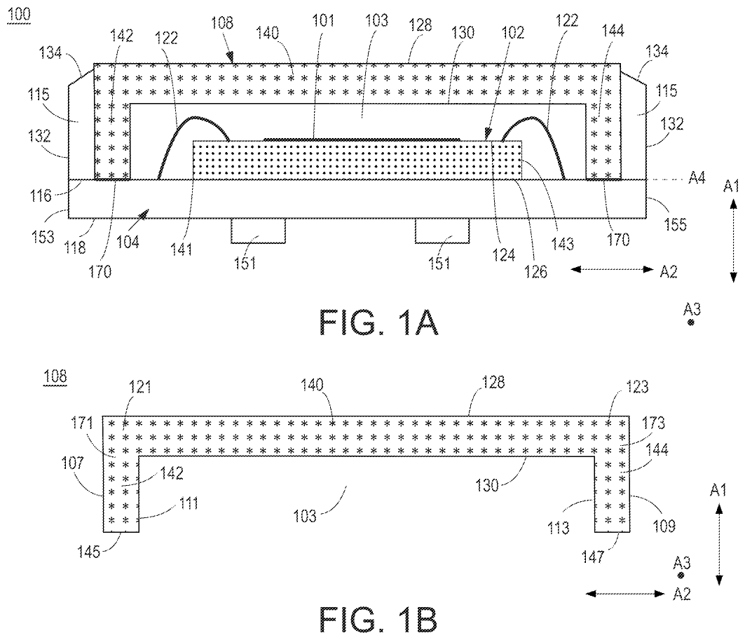

FIG. 1A illustrates an image sensor package 100 according to an aspect. FIG. 1B illustrates a light-transmitting member 108 of the image sensor package 100 according to an aspect. In some examples, the image sensor package 100 includes an interstitial ball grid array (iBGA) package. In some examples, the image sensor package 100 is an automobile image sensor (e.g., an image sensor designed to be incorporated into a vehicle). However, the image sensor package 100 may be applicable to other types of applications.

The image sensor package 100 includes a substrate 104, an image sensor die 102 coupled to the substrate 104, conductors 122 coupled to the image sensor die 102 and the substrate 104, and a light-transmitting member 108. The light-transmitting member 108 defines a cavity 103, which may be a portion of the light-transmitting member 108 that has been removed via etching. The light-transmitting member 108 is coupled to the substrate 104 via a bonding material 170 such that the image sensor die 102 is disposed within the cavity 103 of the light-transmitting member 108. The conductors 122 are also disposed within the cavity 103 of the light-transmitting member 108. The image sensor package 100 includes an encapsulation material 115 that is applied to the substrate 104 and the light-transmitting member 108.

The substrate 104 includes a dielectric material. In some examples, the substrate 104 includes a single layer of dielectric material. In some examples, the substrate 104 includes multiple layers of dielectric material. In some examples, the substrate 104 includes a printed circuit board (PCB) substrate (e.g., a single layer of PCB or multiple layers of PCB). In some examples, the substrate 104 includes a copper clad laminate (CCL) substrate.

The substrate 104 includes a first surface 116 and a second surface 118 that is disposed opposite to the first surface 116. The second surface 118 may be parallel with the first surface 116. The distance between the first surface 116 and the second surface 118 may define the thickness of the substrate 104 in a direction A1. The substrate 104 includes a first edge 153 and a second edge 155. The second edge 155 may be parallel to the first edge 153. The first edge 153 and the second edge 155 may be perpendicular to the first surface 116 and the second surface 118. The distance between the first edge 153 and the second edge 155 may define a length of the substrate 104 in a direction A2. The first surface 116 of the substrate 104 is disposed in a plane A4. A direction A1 is aligned perpendicular to the plane A4, and a direction A2 is perpendicular to the direction A1. A direction A3 into the page (shown as a dot) is aligned parallel to the plane A4 and is orthogonal to directions A1 and A2. The directions A1, A2, and A3, and plane A4, are used throughout several of the various views of the implementations described throughout the figures for simplicity.

In some examples, the substrate 104 includes one or more conductive layer portions (e.g., traces) disposed on the first surface 116 of the substrate 104, and/or one or more conductive layer portions (e.g., traces) disposed on the second surface 118 of the substrate 104. In some examples, the one or more conductive layer portions on the substrate 104 include electrical (or conductive) traces. The electrical traces may be configured to and/or used to transmit signals to and/or from devices (e.g., electronic devices included in a semiconductor region (e.g., epitaxial layer and/or semiconductor substrate) connected to the electrical traces. In some examples, the electrical traces can include conductive traces (e.g., metallic traces) such as copper traces, aluminum traces, and/or so forth. In some examples, the electrical traces include a relatively flat, narrow part of a copper foil that remains after etching. In some examples, the substrate 104 is a CCL substrate with copper traces (on both surfaces) with a pre-preg core (e.g., pre-impregnated with resin), where the copper traces are formed by photolithography patterning from a copper foil.

The image sensor die 102 includes a first surface 124 and a second surface 126. The second surface 126 is disposed in parallel with the first surface 124. The distance between the first surface 124 and the second surface 126 may define the thickness of the image sensor die 102 in the direction A1. The image sensor die 102 includes a first edge 141 and a second edge 143. The second edge 143 is disposed in parallel with the first edge 141. The distance between the first edge 141 and the second edge 143 may define a length of the image sensor die 102 in the direction A2.

The image sensor die 102 includes an active region 101. The active region 101 is defined on a portion of the first surface 124 of the image sensor die 102. The active region 101 includes, or corresponds with, an array of pixel elements configured to convert electromagnetic radiation (e.g., light) to electrical signals. An area outside of the active region 101 may be considered a non-active region. In some examples, the image sensor die 102 includes a complementary metal-oxide semiconductor (CMOS) image sensor. The image sensor die 102 is coupled to the substrate 104. For example, the second surface of the image sensor die 102 is coupled to the first surface 116 of the substrate 104. In some examples, the image sensor die 102 is coupled to the substrate 104 via a bonding material (e.g., a die attach film).

The conductors 122 are connected to the image sensor die 102 and the substrate 104 in order to communicatively couple the image sensor die 102 to the substrate 104. For example, a conductor 122 may be coupled to the first surface 124 (outside the active region 101) of the image sensor die 102, and the first surface 116 of the substrate 104. The conductors 122 may include conductive (e.g., metal) wires such as aluminum, copper, or gold, or any combination thereof, for example. In some examples, the conductors 122 include bond wires. In some examples, the conductors 122 may include conductor members that provide an electrical connection between the image sensor die 102 and the substrate 104.

The light-transmitting member 108 defines a cavity structure that permits a portion of the light-transmitting member 108 to be positioned over the image sensor die 102 and other portions of the light-transmitting member 108 to be coupled to the substrate 104. The light-transmitting member 108 may include an optically transparent material that allows electromagnetic radiation (e.g., light (e.g., visible light)) to pass through (e.g., pass through the entirety of the material). In some examples, the light-transmitting member 108 includes a glass substrate defining the cavity structure. In some examples, the light-transmitting member 108 includes a transparent (or semi-transparent) cover defining the cavity structure. In some examples, the light-transmitting member 108 includes a transparent (or semi-transparent) lid defining the cavity structure. In some examples, the light-transmitting member 108 includes one or more organic materials and/or one or more inorganic materials. In some examples, the light-transmitting member 108 includes one or more layers of transparent material.

The light-transmitting member 108 includes a substrate member 140, a first leg member 142, and a second leg member 144. The substrate member 140, the first leg member 142, and the second leg member 144 may form a single unitary piece of material. In some examples, the substrate member 140 is a linear member that extends in the direction A2. The length of the substrate member 140 in the direction A2 is greater than the length of the image sensor die 102 in the direction A2. The substrate member 140 may include a first surface 128 and a second surface 130. The second surface 130 is disposed in parallel with the first surface 128. The distance between the first surface 128 and the second surface 130 may define the thickness of the substrate member 140 in the direction A1. In some examples, the length of the second surface 130 in the direction A2 is less than the length of the first surface 128 in the direction A2.

The light-transmitting member 108 includes a first edge 107 and a second edge 109. The distance between the first edge 107 and the second edge 109 may define the length of the substrate member 140 (and/or the light-transmitting member 108) in the direction A2. Also, the first edge 107 and the second edge 109 are shared with the first leg member 142 and the second leg member 144, respectively. The substrate member 140 includes a first end portion 121 and a second end portion 123. The first end portion 121 may be the portion of the substrate member 140 that is disposed at one end of the substrate member 140, and the second end portion 123 may be the portion of the substrate member 140 that is disposed at the other end of the substrate member 140 in the direction A2. In some examples, the corners of the substrate member 120 are squared (e.g., the first edge 107 being disposed at a perpendicular angle with the first surface 128, the second edge 109 being disposed at a perpendicular angle with the first surface 128). In some examples, the corners of the substrate 120 are rounded.

The first leg member 142 may extend from the first end portion 121 of the substrate member 140. In some examples, the first leg member 142 extends from the substrate member 140 at a non-zero angle with respect to the substrate member 140. In some examples, at least a portion of the first leg member 142 extends in the direction A1. In some examples, the first leg member 142 (in its entirety) extends in the direction A1. In some examples, the first leg member 142 is disposed at a perpendicular angle with respect to the substrate member 140. In some examples, the first leg member 142 is a linear member that extends in the direction A1. In some examples, the first leg member 142 includes one or more curved or bent portions. The first leg member 142 may include a first end 171 and a second end 145, where a distance between the first end 171 and the second end 145 may define the length of the first leg member 142 in the direction A1. In some examples, the length of the first leg member 142 in the direction A1 is less than the length of the substrate member 140 in the direction A2. Also, the thickness of the first leg member 142 may be defined by the distance between the first edge 107 and a first inner edge 111 in the direction A2. In some examples, the thickness of the first leg member 142 (e.g., in the direction A2) is less than the thickness of the substrate member 140 (e.g., in the direction A1). In some examples, the thickness of the first leg member 142 (e.g., in the direction A2) is equal to (or substantially equal to) the thickness of the substrate member 140 (e.g., in the direction A1).

The second leg member 144 may extend from the second end portion 123 of the substrate member 140. In some examples, the second leg member 144 extends from the substrate member 140 at a non-zero angle with respect to the substrate member 140. In some examples, at least a portion of the second leg member 144 extends in the direction A1. In some examples, the second leg member 144 (in its entirety) extends in the direction A1. In some examples, the second leg member 144 is disposed at a perpendicular angle with respect to the substrate member 140. In some examples, the second leg member 144 is a linear member that extends in the direction A1. In some examples, the second leg member 144 includes one or more curved or bent portions. The second leg member 144 may include a first end 173 and a second end 147, where a distance between the first end 173 and the second end 147 may define the length of the second leg member 144 in the direction A1. In some examples, the length of the second leg member 144 is less than the length of the substrate member 140. Also, the thickness of the second leg member 144 may be defined by the distance between the second edge 109 and a second inner edge 113 in the direction A2. In some examples, the thickness of the second leg member 144 (e.g., in the direction A2) is less than the thickness of the substrate member 140 (e.g., in the direction A1). In some examples, the thickness of the second leg member 144 (e.g., in the direction A2) is equal to (or substantially equal to) the thickness of the substrate member 140 (e.g., in the direction A1).

In some examples, the second leg member 144 may have the same length as the first leg member 142. In some examples, the second leg member 144 may have the same thickness as the first leg member 142. The space between the first leg member 142 and the second leg member 144 defines the cavity 103 of the light-transmitting member 108. For example, the space between the first inner edge 111 and the second inner edge 113 in the direction A2 defines the cavity 103 of the light-transmitting member 108. The space between the second surface 130 of the substrate member 140 and a plane that is aligned with the second end 145 of the first leg member 142 (and the second end 147 of the second leg member 144) in the direction A1 defines the cavity 103 of the light-transmitting member 108.

The first leg member 142 is coupled to the substrate 104 via a bonding material 170 (e.g., an adhesive layer, die attach film, polymer-based material, an epoxy resin, etc.). For example, the second end 145 of the first leg member 142 is coupled to the first surface 116 of the substrate 104 using the bonding material 170. The second leg member 144 is coupled to the substrate 104 via the bonding material 170. For example, the second end 147 of the second leg member 144 is coupled to the first surface 116 of the substrate 104 using the bonding material 170. In some examples, the bonding material 170 has a thickness in the direction A1 that is substantially less than the length of the first leg member 142 and/or the second leg member 144. In some examples, the thickness of the bonding material 170 is less than ten percent of the length of the first leg member 142 and/or the second leg member 144.

As shown in FIG. 1A, the image sensor die 102 is disposed within the cavity 103 of the light-transmitting member 108. Also, at least a portion of the conductors 122 is disposed within the cavity 103 of the light-transmitting member 108. The distance between the active region 101 of the image sensor die 102 and the second surface 130 of the substrate member 140 may define the gap height of the image sensor package 100.

The image sensor package 100 includes conductive components 151 coupled to the second surface 118 of the substrate 104. In some examples, the conductive components 151 are surface-mount packaging elements. In some examples, the conductive components 151 include conductive ball members (e.g., solder balls). The conductive components 151 are components used to connect to an external device (e.g., a ball grid array (BGA) device). However, the conductive components 151 may include other types of surface-mount packaging elements.

The image sensor package 100 includes an encapsulation material 115. The encapsulation material 115 may include one or more molding materials (e.g., in a molding compound if including multiple types of materials). For example, the molding material(s) may include a metal, a plastic, a resin, an epoxy, a phenolic hardener, a silica material, a pigment, a glass, a ceramic casing, and/or so forth.

The encapsulation material 115 includes a portion that contacts the substrate 104, and a portion that contacts and extends along at least a portion the light-transmitting member 108. The encapsulation material 115 may assist with securing the bonded interface of the light-transmitting member 108 and the substrate 104. The encapsulation material 115 contacts a portion of the first surface 116 of the substrate 104 at the end portions (or perimeter portions) of the substrate 104. Also, the encapsulation material 115 contacts and extends along the first leg member 142 and the second leg member 144. The encapsulation material 115 may contact and extend along at least a portion of the first edge 107 and at least a portion of the second edge 109. In some examples, the encapsulation material 115 may extend along the entire length of the first edge 107 in the direction A1 and may extend along the entire length of the second edge 109 in the direction A1. In some examples, although not shown in FIG. 1A, the encapsulation material 115 may contact and extend along a portion of the first surface 128 of the substrate member 140.

In some examples, the encapsulation material 115 includes a first molding edge 132 that defines an end of the encapsulation material 115 in the direction A2. In some examples, the first molding edge 132 is linear. In some examples, the first molding edge 132 includes one or more angled or curved portions. In some examples, at least a portion of the first molding edge 132 (or all of the first molding edge 132) is aligned with the direction A1. In some examples, the first molding edge 132 is disposed at an angle with respect to the direction A2. In some examples, at least a portion of the first molding edge 132 (or all of the first molding edge 132) is aligned with the first edge 153 (or the second edge 155) of the substrate 104. In some examples, the first molding edge 132 is disposed at a location between the first edge 153 (or the second edge 155) of the substrate 104 and first and second edges 107, 109 of the light-transmitting member 108.

The encapsulation material 115 may include a second molding edge 134 defining an end of the encapsulation material 115 in the direction A1. The second molding edge 134 may extend from the first molding edge 132 to the first and second edges 107, 109 of the light-transmitting member 108. In some examples, the second molding edge 134 is disposed at a non-zero angle with respect to the first molding edge 132. In some examples, the second molding edge 134 is disposed at an angle that is perpendicular to the first molding edge 132. In some examples, the second molding edge 134 is linear. In some examples, the second molding edge 134 includes one or more bent or curved portions.

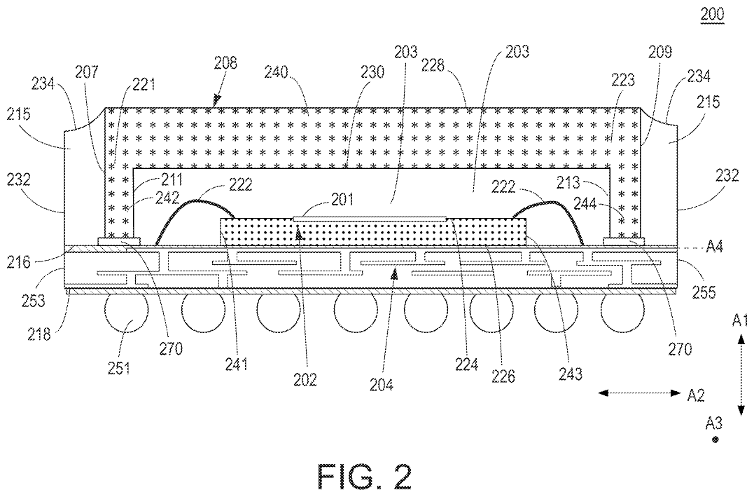

FIG. 2 illustrates an image sensor package 200 according to an aspect. The image sensor package 200 may be an example of the image sensor package 100 of FIGS. 1A and 1B and may include any of the details discussed with reference to that figure. In some examples, the image sensor package 200 includes an interstitial ball grid array (iBGA) package. In some examples, the image sensor package 200 is an automobile image sensor (e.g., an image sensor designed to be incorporated into a vehicle). However, the image sensor package 200 may be applicable to other types of applications.

The image sensor package 200 includes a substrate 204, an image sensor die 202 coupled to the substrate 204, bond wires 222 coupled to the image sensor die 202 and the substrate 204, and a light-transmitting member 208. The light-transmitting member 208 defines a cavity 203, which may be a portion of the light-transmitting member 208 that has been removed via etching. The light-transmitting member 208 is coupled to the substrate 204 via a bonding material 270 such that the image sensor die 202 is disposed within the cavity 203 of the light-transmitting member 208. The bond wires 222 are also disposed within the cavity 203 of the light-transmitting member 208. The image sensor package 200 includes an encapsulation material 215 that is applied to the substrate 204 and the light-transmitting member 208.

The substrate 204 includes a dielectric material. In some examples, the substrate 204 includes a single layer of dielectric material. In some examples, the substrate 204 includes multiple layers of dielectric material. In some examples, the substrate 204 includes a printed circuit board (PCB) substrate (e.g., a single layer of PCB or multiple layers of PCB). In some examples, the substrate 204 includes a copper clad laminate (CCL) substrate.

The substrate 204 includes a first surface 216 and a second surface 218 that is disposed opposite to the first surface 216. The second surface 218 may be parallel with the first surface 216. The distance between the first surface 216 and the second surface 218 may define the thickness of the substrate 204 in a direction A1. The substrate 204 includes a first edge 253 and a second edge 255. The second edge 255 may be parallel to the first edge 253. The first edge 253 and the second edge 255 may be perpendicular to the first surface 216 and the second surface 218. The distance between the first edge 253 and the second edge 255 may define a length of the substrate 204 in a direction A2. The first surface 216 of the substrate 204 is disposed in a plane A4. A direction A1 is aligned perpendicular to the plane A4, and a direction A2 is perpendicular to the direction A1. A direction A3 into the page (shown as a dot) is aligned parallel to the plane A4 and is orthogonal to directions Al and A2.

The image sensor die 202 includes a first surface 224 and a second surface 226. The second surface 226 is disposed in parallel with the first surface 224. The distance between the first surface 224 and the second surface 226 may define the thickness of the image sensor die 202 in the direction A1. The image sensor die 202 includes a first edge 241 and a second edge 243. The second edge 243 is disposed in parallel with the first edge 241. The distance between the first edge 241 and the second edge 243 may define a length of the image sensor die 202 in the direction A2.

The image sensor die 202 includes an active region 201. The active region 201 is defined on a portion of the first surface 224 of the image sensor die 202. The active region 201 includes, or corresponds with, an array of pixel elements configured to convert electromagnetic radiation (e.g., light) to electrical signals. An area outside of the active region 201 may be considered a non-active region. In some examples, the image sensor die 202 includes a complementary metal-oxide semiconductor (CMOS) image sensor. The image sensor die 202 is coupled to the substrate 204. For example, the second surface of the image sensor die 202 is coupled to the first surface 216 of the substrate 204. In some examples, the image sensor die 202 is coupled to the substrate 204 via a bonding material (e.g., a die attach film).

The bond wires 222 are connected to the image sensor die 202 and the substrate 204 in order to communicatively couple the image sensor die 202 to the substrate 204. For example, a bond wire 222 may be coupled to the first surface 224 (outside the active region 201) of the image sensor die 202, and the first surface 216 of the substrate 204. The bond wires 222 may include conductive (e.g., metal) wires such as aluminum, copper, or gold, or any combination thereof, for example.

The light-transmitting member 208 defines a cavity structure that permits a portion of the light-transmitting member 208 to be positioned over the image sensor die 202 and other portions of the light-transmitting member 208 to be coupled to the substrate 204. The light-transmitting member 208 includes a substrate member 240, a first leg member 242, and a second leg member 244. The substrate member 240, the first leg member 242, and the second leg member 244 may form a single unitary piece of material. In some examples, the substrate member 240 is a linear member that extends in the direction A2. The length of the substrate member 240 in the direction A2 is greater than the length of the image sensor die 202 in the direction A2. The substrate member 240 may include a first surface 228 and a second surface 230. The second surface 230 is disposed in parallel with the first surface 228. The distance between the first surface 228 and the second surface 230 may define the thickness of the substrate member 240 in the direction A1. In some examples, the length of the second surface 230 in the direction A2 is less than the length of the first surface 228 in the direction A2.

The light-transmitting member 208 includes a first edge 207 and a second edge 209. The distance between the first edge 207 and the second edge 209 may define the length of the substrate member 240 (and/or the light-transmitting member 208) in the direction A2. Also, the first edge 207 and the second edge 209 are shared with the first leg member 242 and the second leg member 244, respectively. The substrate member 240 includes a first end portion 221 and a second end portion 223. The first end portion 221 may be the portion of the substrate member 240 that is disposed at one end of the substrate member 240, and the second end portion 223 may be the portion of the substrate member 240 that is disposed at the other end of the substrate member 240 in the direction A2.

The first leg member 242 may extend from the first end portion 221 of the substrate member 240. In some examples, the first leg member 242 extends from the substrate member 240 at a non-zero angle with respect to the substrate member 240. In some examples, at least a portion of the first leg member 242 extends in the direction A1. In some examples, the first leg member 242 (in its entirety) extends in the direction A1. In some examples, the first leg member 242 is disposed at a perpendicular angle with respect to the substrate member 240. In some examples, the first leg member 242 is a linear member that extends in the direction A1. In some examples, the first leg member 242 includes one or more curved or bent portions. In some examples, the length of the first leg member 242 in the direction A1 is less than the length of the substrate member 240 in the direction A2. Also, the thickness of the first leg member 242 may be defined by the distance between the first edge 207 and a first inner edge 211 in the direction A2. In some examples, the thickness of the first leg member 242 (e.g., in the direction A2) is less than the thickness of the substrate member 240 (e.g., in the direction A1). In some examples, the thickness of the first leg member 242 (e.g., in the direction A2) is equal to (or substantially equal to) the thickness of the substrate member 240 (e.g., in the direction A1).

The second leg member 244 may extend from the second end portion 223 of the substrate member 240. In some examples, the second leg member 244 extends from the substrate member 240 at a non-zero angle with respect to the substrate member 240. In some examples, at least a portion of the second leg member 244 extends in the direction A1. In some examples, the second leg member 244 (in its entirety) extends in the direction A1. In some examples, the second leg member 244 is disposed at a perpendicular angle with respect to the substrate member 240. In some examples, the second leg member 244 is a linear member that extends in the direction A1. In some examples, the second leg member 244 includes one or more curved or bent portions. In some examples, the length of the second leg member 244 is less than the length of the substrate member 240. Also, the thickness of the second leg member 244 may be defined by the distance between the second edge 209 and a second inner edge 213 in the direction A2. In some examples, the thickness of the second leg member 244 (e.g., in the direction A2) is less than the thickness of the substrate member 240 (e.g., in the direction A1). In some examples, the thickness of the second leg member 244 (e.g., in the direction A2) is equal to (or substantially equal to) the thickness of the substrate member 240 (e.g., in the direction A1).

In some examples, the second leg member 244 may have the same length as the first leg member 242. In some examples, the second leg member 244 may have the same thickness as the first leg member 242. The space between the first leg member 242 and the second leg member 244 defines the cavity 203 of the light-transmitting member 208. For example, the space between the first inner edge 211 and the second inner edge 213 in the direction A2 defines the cavity 203 of the light-transmitting member 208. The space between the second surface 230 of the substrate member 240 and a plane that is aligned with the second end of the first leg member 242 (and the second end of the second leg member 244) in the direction A1 defines the cavity 203 of the light-transmitting member 208.

The first leg member 242 is coupled to the substrate 204 via a bonding material 270 (e.g., an adhesive layer, die attach film, polymer-based material, an epoxy resin, etc.). For example, the first leg member 242 is coupled to the first surface 216 of the substrate 204 using the bonding material 270. The second leg member 244 is coupled to the substrate 204 via the bonding material 270. For example, the second leg member 244 is coupled to the first surface 216 of the substrate 204 using the bonding material 270. In some examples, the bonding material 270 has a thickness in the direction A1 that is substantially less than the length of the first leg member 242 and/or the second leg member 244. In some examples, the thickness of the bonding material 270 is less than ten percent of the length of the first leg member 242 and/or the second leg member 244. In some examples, the width of the bonding material 270 in the direction A2 is greater than the width of the first leg member 242 and the second leg member 244 in the direction A2.

As shown in FIG. 2, the image sensor die 202 is disposed within the cavity 203 of the light-transmitting member 208. Also, at least a portion of the bond wires 222 is disposed within the cavity 203 of the light-transmitting member 208. The distance between the active region 201 of the image sensor die 202 and the second surface 230 of the substrate member 240 may define the gap height of the image sensor package 200.

The image sensor package 200 includes conductive components 251 coupled to the second surface 218 of the substrate 204. In some examples, the conductive components 251 are surface-mount packaging elements. In some examples, the conductive components 251 include conductive ball members (e.g., solder balls). The conductive components 251 are components used to connect to an external device (e.g., a ball grid array (BGA) device). However, the conductive components 251 may include other types of surface-mount packaging elements.

The image sensor package 200 includes an encapsulation material 215. The encapsulation material 215 may include one or more molding materials (e.g., in a molding compound if including multiple types of materials). For example, the molding material(s) may include a metal, a plastic, a resin, an epoxy, a phenolic hardener, a silica material, a pigment, a glass, a ceramic casing, and/or so forth.

The encapsulation material 215 includes a portion that contacts the substrate 204, and a portion that contacts and extends along at least a portion the light-transmitting member 208. The encapsulation material 215 may assist with securing the bonded interface of the light-transmitting member 208 and the substrate 204. The encapsulation material 215 contacts a portion of the first surface 216 of the substrate 204 at the end portions (or perimeter portions) of the substrate 204. Also, the encapsulation material 215 contacts and extends along the first leg member 242 and the second leg member 244. The encapsulation material 215 may contact and extend along at least a portion of the first edge 207 and at least a portion of the second edge 209. In some examples, the encapsulation material 215 may extend along the entire length of the first edge 207 in the direction A1 and may extend along the entire length of the second edge 209 in the direction A1. In some examples, although not shown in FIG. 2, the encapsulation material 215 may contact and extend along a portion of the first surface 228 of the substrate member 240.

The encapsulation material 215 includes a first molding edge 232 that defines an end of the encapsulation material 215 in the direction A2. In some examples, the first molding edge 232 is linear. In some examples, the first molding edge 232 includes one or more angled or curved portions. In some examples, at least a portion of the first molding edge 232 (or all of the first molding edge 232) is aligned with the direction A1. In some examples, the first molding edge 232 is disposed at an angle with respect to the direction A2. In some examples, at least a portion of the first molding edge 232 (or all of the first molding edge 232) is aligned with the first edge 253 (or the second edge 255) of the substrate 204. In some examples, the first molding edge 232 is disposed at a location between the first edge 253 (or the second edge 255) of the substrate 204 and first and second edges 207, 209 of the light-transmitting member 208.

The encapsulation material 215 may include a second molding edge 234 defining an end of the encapsulation material 215 in the direction A1. The second molding edge 234 may extend from the first molding edge 232 to the first and second edges 207, 209 of the light-transmitting member 208. In some examples, the second molding edge 234 is disposed at a non-zero angle with respect to the first molding edge 232. In some examples, the second molding edge 234 is disposed at an angle that is perpendicular to the first molding edge 232. In some examples, the second molding edge 234 is linear. In some examples, the second molding edge 234 includes one or more bent or curved portions.

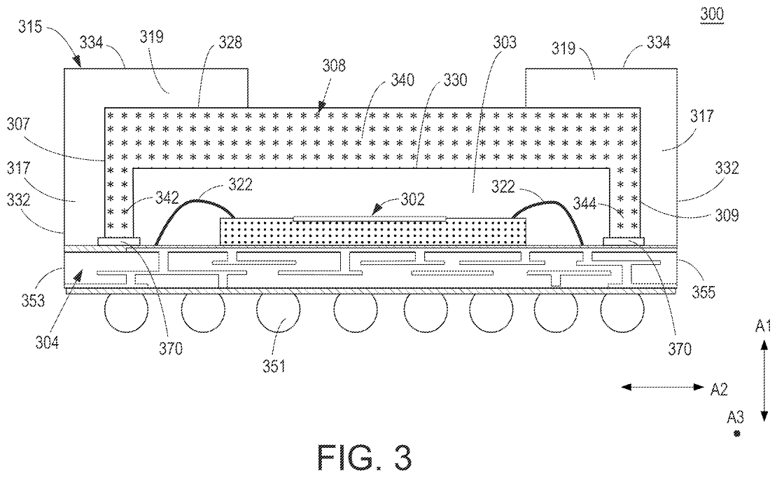

FIG. 3 illustrates an image sensor package 300 according to an aspect. The image sensor package 300 may be an example of the image sensor package 100 of FIGS. 1A and 1B and/or the image sensor package 200 of FIG. 2 and may include any of the details discussed herein. For example, the image sensor package 300 may be similar to the image sensor package 100 of FIGS. 1A and 1B and the image sensor package 200 of FIG. 2 except that an encapsulation material 315 extends over a first surface 328 of a substrate member 340 of a light-transmitting member 308.

The image sensor package 300 includes a substrate 304, an image sensor die 302 coupled to the substrate 304, bond wires 322 coupled to the image sensor die 302 and the substrate 304, and a light-transmitting member 308. The light-transmitting member 308 defines a cavity 303, which may be a portion of the light-transmitting member 308 that has been removed via etching. The light-transmitting member 308 is coupled to the substrate 304 via a bonding material 370 such that the image sensor die 302 is disposed within the cavity 303 of the light-transmitting member 308. The bond wires 322 are also disposed within the cavity 303 of the light-transmitting member 308. The image sensor package 300 includes an encapsulation material 315 that is applied to the substrate 304 and the light-transmitting member 308. The light-transmitting member 308 includes a substrate member 340, a first leg member 342, and a second leg member 344. The substrate member 340 includes a first surface 328 and a second surface 330. The image sensor package 300 includes a plurality of conductive components 351 coupled to the substrate 304.

The image sensor package 300 includes an encapsulation material 315. The encapsulation material 315 may include one or more molding materials (e.g., in a molding compound if including multiple types of materials). For example, the molding material(s) may include a metal, a plastic, a resin, an epoxy, a phenolic hardener, a silica material, a pigment, a glass, a ceramic casing, and/or so forth.

The encapsulation material 315 includes a molding portion 317 that contacts the substrate 304. The molding portion 317 may extend along the direction A1. The molding portion 317 also contacts and extends along at least a portion the first leg member 342 and the second leg member 344. The molding portion 317 may extend along a first edge 307 of the light-transmitting member 308 in the direction A1. The molding portion 317 may extend along a second edge 309 of the light-transmitting member 308 in the direction A1.

The encapsulation material 315 includes a first molding edge 332 that defines an end of the encapsulation material 315 in the direction A2. In some examples, the first molding edge 332 is linear. In some examples, the first molding edge 332 has a length in the direction A1 that is greater than the length of the first edge 307 and the second edge 309 in the direction A1. In some examples, the first molding edge 332 includes one or more angled or curved portions. In some examples, at least a portion of the first molding edge 332 (or all of the first molding edge 332) is aligned with the direction A1. In some examples, the first molding edge 332 is disposed at an angle with respect to the direction A2. In some examples, at least a portion of the first molding edge 332 (or all of the first molding edge 332) is aligned with a first edge 353 (or a second edge 355) of the substrate 304. In some examples, the first molding edge 332 is disposed at a location between the first edge 353 (or the second edge 355) of the substrate 304 and first and second edges 307, 309 of the light-transmitting member 308.

The encapsulation material 315 includes a molding portion 319 that contacts and extends along a portion (e.g., a perimeter portion) of the first surface 328 of the substrate member 340. The molding portion 319 may extend along the direction A2.

The encapsulation material 315 may include a second molding edge 334 defining an end of the encapsulation material 315 in the direction A1. The second molding edge 334 may extend from the first molding edge 332. In some examples, the second molding edge 334 is disposed at a non-zero angle with respect to the first molding edge 332. In some examples, the second molding edge 334 is disposed at an angle that is perpendicular to the first molding edge 332. In some examples, the second molding edge 334 is linear. In some examples, the corners of the encapsulation material 315 (e.g., formed by the first molding edge 332 and the second molding edge 332) is square. In some examples, the corners of the encapsulation material 315 are rounded. In some examples, the second molding edge 334 includes one or more bent or curved portions.

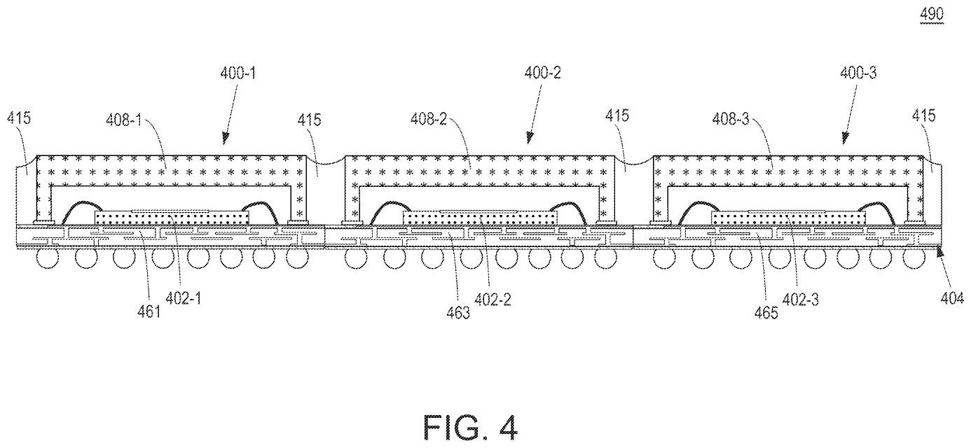

FIG. 4 illustrates an image sensor strip assembly 490 having multiple image sensor packages. For example, the image sensor strip assembly 490 may define individual image sensor packages that share a common substrate 404. An encapsulation material 415 is disposed between each image sensor package. The substrate 404 and the encapsulation material 415 is cut to create individual image sensor packages.

The image sensor strip assembly 490 may define a first image sensor package 400-1, a second image sensor package 400-2, and a third image sensor package 400-3. The first image sensor package 400-1, the second image sensor package 400-2, or the third image sensor package 400-3 may be an example of the image sensor package 100 of FIGS. 1A and 1B, the image sensor package 200 of FIG. 2, or the image sensor package 300 of FIG. 3 and may include any of the details discussed with reference to those figures. Although FIG. 4 depicts three image sensor packages, the image sensor strip assembly 490 may define any number of image sensor packages including two image sensor packages or more than three image sensor packages.

The image sensor strip assembly 490 includes a substrate 404, a first image sensor die 402-1 coupled to a first portion 461 of the substrate 404, a first light-transmitting member 408-1 coupled to the first portion 461 of the substrate 404, a second image sensor die 402-2 coupled to a second portion 463 of the substrate 404, a second light-transmitting member 408-2 coupled to the second portion 463 of the substrate 404, a third image sensor die 402-3 coupled to a third portion 465 of the substrate 404, and a third light-transmitting member 408-3 coupled to the third portion 465 of the substrate 404.

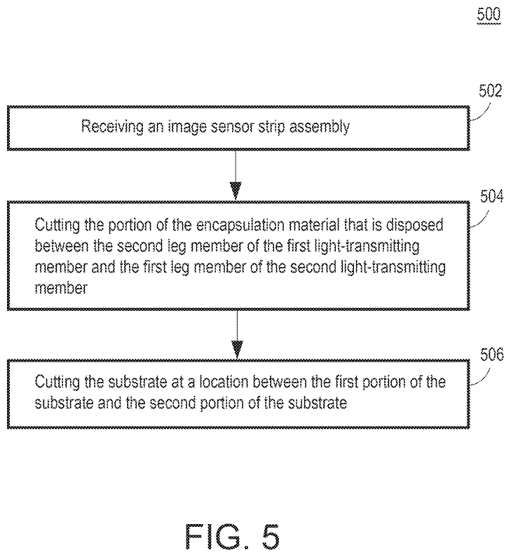

FIG. 5 depicts a flowchart 500 having example operations for creating individual image sensor packages according to an aspect. Although the flowchart 500 is explained with the image sensor strip assembly 490 of FIG. 4, the flowchart 500 may be applicable to any of the embodiments discussed herein. Although the flowchart 500 of FIG. 5 illustrates operations in sequential order, it will be appreciated that this is merely an example, and that additional or alternative operations may be included. Further, operations of FIG. 5 and related operations may be executed in a different order than that shown, or in a parallel or overlapping fashion.

Operation 502 includes receiving an image sensor strip assembly 490. Operation 504 includes cutting the portion of the encapsulation material 415 that is disposed between the second leg member of the first light-transmitting member 408-1 and the first leg member of the second light-transmitting member 408-2. Operation 506 includes cutting the substrate 404 at a location between the first portion 461 of the substrate 404 and the second portion 463 of the substrate 404.

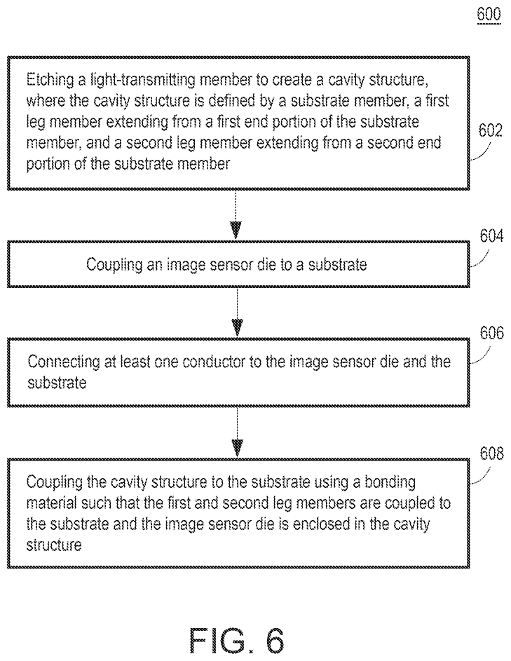

FIG. 6 depicts a flowchart 600 having example operations for assembling an image sensor package according to an aspect. Although the flowchart 600 is explained with the image sensor package 100 of FIG. 1, the flowchart 600 may be applicable to any of the embodiments discussed herein. Although the flowchart 600 of FIG. 6 illustrates operations in sequential order, it will be appreciated that this is merely an example, and that additional or alternative operations may be included. Further, operations of FIG. 6 and related operations may be executed in a different order than that shown, or in a parallel or overlapping fashion.

Operation 602 includes etching a light-transmitting member 108 to create a cavity structure, where the cavity structure is defined by a substrate member 140, a first leg member 142 extending from a first end portion 121 of the substrate member 140, and a second leg member 144 extending from a second end portion 123 of the substrate member 140. Operation 604 includes coupling an image sensor die 102 to a substrate 104. Operation 606 includes connecting at least one conductor 122 to the image sensor die 102 and the substrate 104. Operation 608 includes coupling the cavity structure to the substrate 104 using a bonding material 170 such that the first and second leg members 142, 144 are coupled to the substrate 104 and the image sensor die 102 is enclosed in the cavity structure.

It will be understood that, in the foregoing description, when an element is referred to as being connected to, electrically connected to, coupled to, or electrically coupled to another element, it may be directly connected or coupled to the other element, or one or more intervening elements may be present. In contrast, when an element is referred to as being directly connected to or directly coupled to another element, there are no intervening elements. Although the terms directly connected to, or directly coupled to may not be used throughout the detailed description, elements that are shown as being directly connected or directly coupled can be referred to as such. The claims of the application, if any, may be amended to recite exemplary relationships described in the specification or shown in the figures. Implementations of the various techniques described herein may be implemented in (e.g., included in) digital electronic circuitry, or in computer hardware, firmware, software, or in combinations of them. Portions of methods also may be performed by, and an apparatus may be implemented as, special purpose logic circuitry, e.g., an FPGA (field programmable gate array) or an ASIC (application specific integrated circuit).

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments. It should be understood that they have been presented by way of example only, not limitation, and various changes in form and details may be made. Any portion of the apparatus and/or methods described herein may be combined in any combination, except mutually exclusive combinations. The embodiments described herein can include various combinations and/or sub-combinations of the functions, components and/or features of the different embodiments described.

What is claimed is:

1. An image sensor package comprising:
a substrate;
an image sensor die coupled to the substrate;
at least one conductor connected to the image sensor die and the substrate; and
a light-transmitting member including a substrate member, a first leg member extending from a first edge portion of the substrate member, and a second leg member extending from a second edge portion of the substrate member, the first leg member being coupled to the substrate, the second leg member being coupled to the substrate.

2. The image sensor package of claim 1, wherein the light-transmitting member includes a cavity that extends between the first leg member and the second leg member.

3. The image sensor package of claim 2, wherein the image sensor die is disposed within the cavity.

4. The image sensor package of claim 2, wherein at least a portion of the at least one conductor is disposed within the cavity.

5. The image sensor package of claim 1, wherein the first leg member is coupled to the substrate with a bonding material, and the second leg member is coupled to the substrate with a bonding material.

6. The image sensor package of claim 1, wherein the substrate member is a linear body having a length greater than a length of the image sensor die, the substrate member including a first surface and a second surface, the first leg member extending from the second surface at a first non-zero angle with respect to the second surface, the second leg member extending from the second surface at a second non-zero angle with respect to the second surface.

7. The image sensor package of claim 6, wherein the first non-zero angle is a perpendicular angle, and the second non-zero angle is a perpendicular angle.

8. The image sensor package of claim 1, further comprising:
an encapsulation material including a first portion that contacts at least a portion of the first leg member and a second portion that contacts at least a portion of the second leg member.

9. The image sensor package of claim 1, wherein the substrate includes a first surface and a second surface, the image sensor die being coupled to the first surface, the image sensor package further comprising:
a plurality of conductive components coupled to the second surface of the substrate, the plurality of conductive components configured to be connected to an external device.

10. The image sensor package of claim 1, wherein the image sensor package is an interstitial ball grid array (iBGA) package.

11. An image sensor strip assembly having multiple image sensor packages, the image sensor strip assembly comprising:
a substrate;
a first image sensor die coupled to a first portion of the substrate;
a first light-transmitting member coupled to the first portion of the substrate, the first light-transmitting member including a substrate member, a first leg member extending from the substrate member, and a second leg member extending from the substrate member;
a second image sensor die coupled to a second portion of the substrate; and
a second light-transmitting member coupled to the second portion of the substrate, the second light-transmitting member including a substrate member, a first leg member extending from the substrate member, and a second leg member extending from the substrate member.

12. The image sensor strip assembly of claim 11, further comprising:
an encapsulation material including a portion disposed between the second leg member of the first light-transmitting member and the first leg member of the second light-transmitting member.

13. The image sensor strip assembly of claim 12, further comprising:
a third image sensor die coupled to a third portion of the substrate; and
a third light-transmitting member coupled to the third portion of the substrate, the third light-transmitting member including a substrate member, a first leg member extending from the substrate member, and a second leg member extending from the substrate member,
wherein the encapsulation material includes a portion disposed between the second leg member of the second light-transmitting member and the first leg member of the third light-transmitting member.

14. The image sensor strip assembly of claim 11, wherein the first leg member of the first light-transmitting member is coupled to the first portion of the substrate, and the second leg member of the first light-transmitting member is coupled to the first portion of the substrate.

15. The image sensor strip assembly of claim 11, further comprising:
at least one first conductor connected to the first image sensor die and the first portion of the substrate; and
at least one second conductor connected to the second image sensor die and the second portion of the substrate.

16. The image sensor strip assembly of claim 11, wherein the first leg member of the first light-transmitting member is coupled to the first portion of the substrate with a bonding material, and the second leg member of the first light-transmitting member is coupled to the first portion of the substrate with a bonding material.

17. The image sensor strip assembly of claim 11, wherein the substrate member of the first light-transmitting member is a linear body having a length greater than a length of the first image sensor die, the substrate member of the first light-transmitting member including a first surface and a second surface, the first leg member of the first light-transmitting member extending from the second surface at a perpendicular angle with respect to the second surface, the second leg member of the first light-transmitting member extending from the second surface at a perpendicular angle with respect to the second surface.

18. The image sensor strip assembly of claim 11, wherein the substrate includes a first surface and a second surface, the first image sensor die being coupled to the first surface, the second image sensor die being coupled to the first surface, the image sensor strip assembly further comprising:
a plurality of solder balls coupled to the second surface of the substrate, the plurality of solder balls configured to be connected to an external device.

19. A method of creating individual image sensor packages, the method comprising:
receiving an image sensor strip assembly, the image sensor strip assembly including:
a substrate;
a first image sensor die coupled to a first portion of the substrate;
a first light-transmitting member coupled to the first portion of the substrate, the first light-transmitting member including a substrate member, a first leg member extending from the substrate member, and a second leg member extending from the substrate member;
a second image sensor die coupled to a second portion of the substrate;
a second light-transmitting member coupled to the second portion of the substrate, the second light-transmitting member including a substrate member, a first leg member extending from the substrate member, and a second leg member extending from the substrate member; and
an encapsulation material including a portion disposed between the second leg member of the first light-transmitting member and the first leg member of the second light-transmitting member;
cutting the portion of the encapsulation material that is disposed between the second leg member of the first light-transmitting member and the first leg member of the second light-transmitting member; and
cutting the substrate at a location between the first portion of the substrate and the second portion of the substrate.

20. A method of forming an image sensor package, the method comprising:
etching a light-transmitting member to create a cavity structure, the cavity structure being defined by a substrate member, a first leg member extending from a first edge portion of the substrate member, and a second leg member extending from a second edge portion of the substrate member;
coupling an image sensor die to a substrate;
connecting at least one conductor to the image sensor die and the substrate; and
coupling the cavity structure to the substrate using a bonding material such that the first and second leg members are coupled to the substrate and the image sensor die is enclosed in the cavity structure.
